(19) United States
(12) Patent Application Publication
(10) Pub. No.: US 2016/0156287 A1
(43) Pub. Date: Jun. 2, 2016

(54) HALF-TUBE ARRAY VIBRATION ENERGY HARVESTING METHOD USING PIEZOELECTRIC MATERIALS

(71) Applicants: Zhengbao Yang, Toronto (CA); Jean Zu, Toronto (CA)

(72) Inventors: Zhengbao Yang, Toronto (CA); Jean Zu, Toronto (CA)

(21) Appl. No.: 14/953,241

(22) Filed: Nov. 27, 2015

Related U.S. Application Data
(60) Provisional application No. 62/085,414, filed on Nov. 28, 2014.

(51) Int. Cl. H02N 2/18; H01L 41/18; H01L 41/113

(52) U.S. Cl. CPC H02N 2/188; H01L 41/1134; H01L 41/18

(57) ABSTRACT

A piezoelectric transducer for harvesting ambient vibration energy is made up of a curved substructure beam, two half-tube piezoelectric elements and a mass block. One end of the beam is fixed on a vibration base and the other end is attached with the mass block. Two half-tube piezoelectric elements are affixed on the surface of the curved substructure beam. The present invention has a high energy transformation efficiency and a low resonance frequency. It can be applied in implantable devices, wearable electronics and wireless sensor networks.

### RELATED APPLICATION

The present invention request the priority date of the provisional patent application No. 62/085,414 filed Nov. 28, 2014.

### FIELD OF THE INVENTION

The invention is related to a method to harvest ambient vibration energy.

### BACKGROUND OF THE INVENTION

Energy harvesting is a new technology by which vibration energy from external vibration sources (e.g. vehicles, machines, buildings, and human motions) are captured and stored for later use by low-power electronic devices. Conventional power sources, such as batteries, have some intrinsic limitations, such as short lifetime and small capacity. In addition, it is difficult to minimized the size of electrochemical batteries for applications in small devices, such as in micro-electromechanical systems. The energy harvesting technology can eliminate obstacles set by batteries and fulfill the vision for self-powered electronic devices.

There are several energy sources for energy harvesting applications, including heat, sun, wind and vibration energy. Among them, vibration energy is the only one that does not depend on weather conditions. Furthermore, vibration energy is abundant and ubiquitous in the surroundings. Currently, there are mainly three methods for harvesting vibration energy: electromagnetic, electrostatic and piezoelectric conversion methods. The piezoelectric method has the advantage of being easy to scale, no separate voltage sources, and having a high energy density.

Most energy harvesters are based on a cantilever beam, in which one end of the beam is fixed on a vibration base and its other end is attached to a mass block. The mass block allows the device to capture more inertial energy and to reduce the resonance frequency of the system. Piezoelectric patches are glued on the surface of the cantilever beam near its fixed end. The base vibration causes a periodic bending of the cantilever beam, which leads to the formation of stresses in the piezoelectric patches. The energies associated with the stresses are converted to electrical energy by the piezoelectric effect. For example in ‘Nagashima, Susumu, and Ryotaro Matsumura. “Piezoelectric Generator.” US 20100244629 A1’, a rectangular elastic plate is preliminary bent in an arc shape and fixed at both ends. A flat piezo plate is glued on the surface of the bent elastic plate near the fixed end, and a spacer block is placed between the bent elastic plate and a flat base. Once external force loads or vibration excitations are applied to the structure, the bent arc plate and the piezoelectric plate on it will deform and then electricity is generated. Although this invention tries to use an arc beam structure, the core part is still a 2D flat piezoelectric plate. Another example is ‘Churchill, David L., et al. “Wide-band vibration energy harvester with stop.” U.S. Pat. No. 8,154,177 B1, 2012’. This invention is to use the buckling effect to have a wide working bandwidth. A piezo fiber composite plate is fixed at one end. The other end is applied by a load first and then fixed. Because the piezo fiber composite plate is not attached to anything except the two fixed end, it will vibrate up and down between the two buckled states when it is excited. By the jump between the two states, the strain/stress developed on the surface of the piezo fiber composite plate is used to generate electricity. This invention takes advantage of the nonlinear vibration from a buckled beam, but still uses a flat piezoelectric element.

The prior art provides a variety of bean designs to improve the performance the energy harvester. These designs include a doubly-clamped beam, a curved beam, a vertically-laid beam, a non-uniform beam, and a beam array. The main issue with the currently available energy harvesters is their low efficiency, and that they cannot provide enough power for most applications.

### SUMMARY OF THE INVENTION

The primary objective of the present invention is accordingly to provide an effective approach to improve the efficiency of piezoelectric energy harvesters. A common element in all of the prior piezoelectric based energy harvesting devices is a flat piezoelectric element. The present energy harvester utilizes an array of curved (half-tube) piezoelectric elements, which is shown to significantly increase the energy output of piezoelectric based energy harvesters. Such “half-tube array vibration energy harvester (HA-VEH), employ 3-D curved topology tubes instead of 2-D flat plates, which significantly improve the efficiency as well as lowering the resonance frequency of the harvester.

The new energy harvester comprises a curved substructure beam, an array of half-tube piezoelectric elements and a mass block. One end of the substructure beam is fixed on a vibration base and the other end is attached to the mass block. An array (e.g., one or more) of curved (e.g., half-tube) piezoelectric elements are attached on the surface of the curved substructure beam. The piezoelectric elements are polarized in the radial direction and have electrode layers on both surfaces. The substructure beam and the piezoelectric elements have the same curved shape to fit on each other. The array of curved (e.g., half-circle) piezoelectric elements are electrically connected in series along their longitudinal direction for greater power output.

Further features and advantages of the invention will be apparent to those skilled in the art from the following detailed description, taken together with the accompanying drawings.

### BRIEF DESCRIPTION OF THE DRAWINGS

Embodiments herein will hereinafter be described in conjunction with the appended drawings provided, to illustrate and not to limit the scope of the claims, wherein like designations denote like elements, and in which:

FIG. 1 is a schematic diagram depicting a first embodiment of a half-tube array vibration energy harvester according to the present invention;

FIG. 2 shows the polarization direction of the half-tube piezoelectric element;

FIG. 3A is a schematic diagram depicting a second embodiment of the present invention with one half-tube piezoelectric element;

FIG. 3B is a schematic diagram depicting a third embodiment of the present invention with three half-tube piezoelectric elements;

FIG. 4 is a schematic diagram depicting a fourth embodiment of the present invention where both inner side and outer side of the surface of the substructure beam are attached with half-tube piezoelectric elements, forming a bimorph-style composite structure.

FIG. 5 is a schematic diagram depicting a fifth embodiment of the present invention where both ends of the substructure beam are fixed.

FIG. 6 is a figure showing the results of a comparison experiment of the present invention and the conventional energy harvester.

### DETAILED DESCRIPTION OF PREFERRED EMBODIMENTS

The present invention comprises of an array of curved (e.g., half-tube) vibration energy harvester (HA-VEH) using piezoelectric materials. This invention provides a higher efficiency energy harvesting devices as compared to the prior art. A higher efficiency and a higher power generation based on the same vibration energy is obtained due to using a curves, three dimensional, piezoelectric element attached to a curved beam.

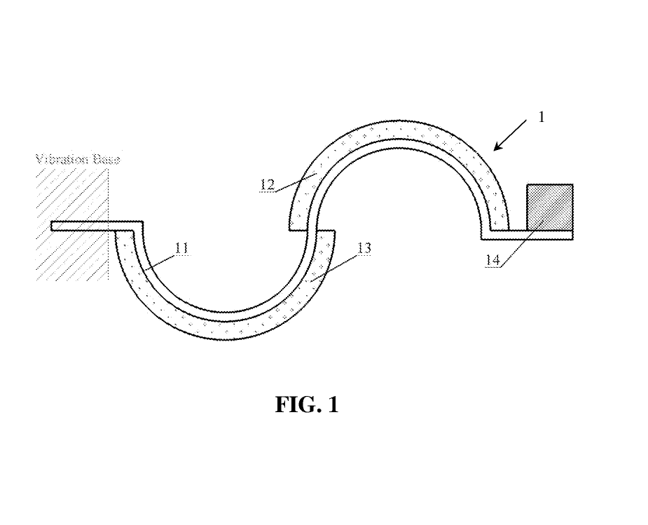

FIG. 1 schematically illustrates a first embodiment 1 according to the present invention, comprising of a curved substructure beam 11, two half-tube piezoelectric elements 12 and 13, and a mass block 14. The half-tube piezoelectric elements 12 and 13 are positioned serially on the outer surface of the substructure beam 11 along the longitudinal direction of the beam. One end of the substructure beam 11 is fixed on a vibration base and the other end is attached to a mass block 14.

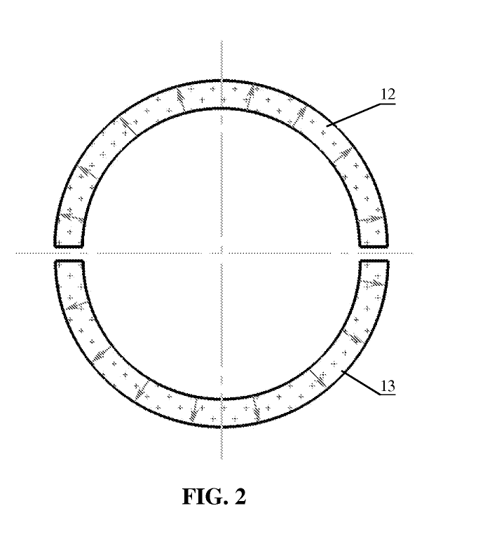

FIG. 2 demonstrates how the half-tube piezoelectric elements 12 and 13 are polarized. Unlike energy harvesters employing piezoelectric plates or discs that are polarized along the x (y or z) axis, we polarize the half-tube piezoelectric element herein along the radial direction. The morphology of the half-tube piezoelectric element can be a standard half circle or smaller or bigger than a half circle. Other 3D morphologies can be designed by conducting finite element analysis to maximize and homogenize the induced stress.

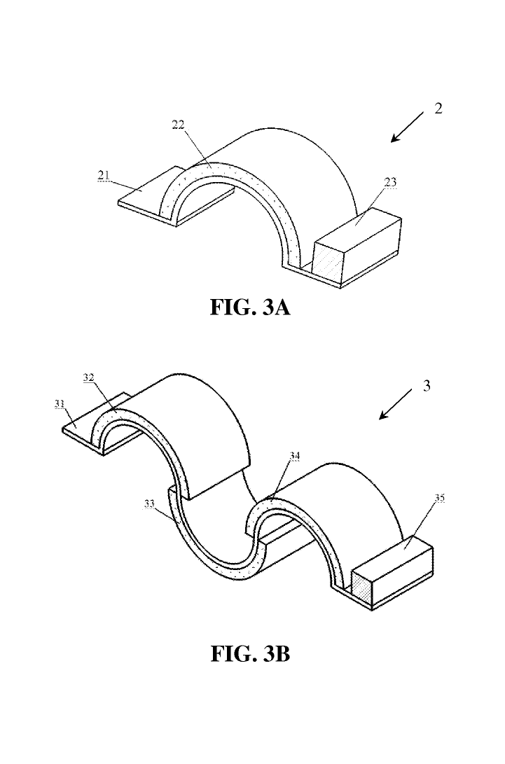

FIG. 3A and FIG. 3B show a second and a third embodiment of the present invention where one and three half-tube piezoelectric elements are employed, respectively. In the second embodiment 2 of FIG. 3A, the curved substructure beam 21 is fixed on a vibration base and a mass block 23 is added to the other end of the substructure beam 21. One half-tube piezoelectric element 23 is attached on the surface of the curved substructure beam 21. In the third embodiment 3, the substructure beam 31 has three curves and it is fixed at one end and attached to a mass block 35 at the other free end. Three half-tube piezoelectric elements 32-34 are connected serially along the longitudinal direction of the substructure beam. It is obvious that one can combine more half-tube elements depending on the specification of a particular application.

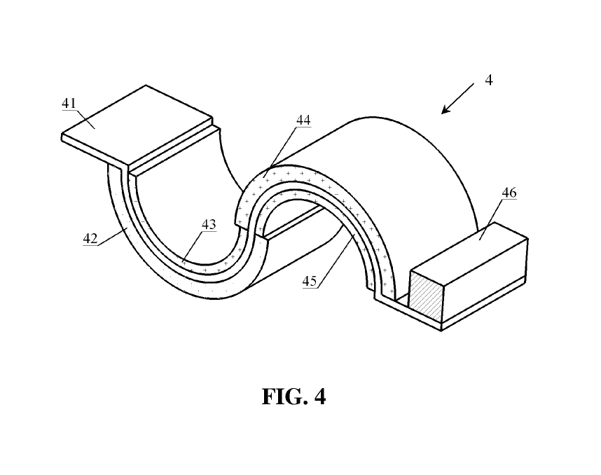

FIG. 4 is a schematic diagram depicting a fourth embodiment 4 of the present invention that has a bimorph-style composite structure. In this embodiment 4, one end of the substructure beam 41 is fixed on a vibration base and the other end is attached to a mass block 46. There are four half-tube piezoelectric elements (42, 43, 44, 45) wherein each two (42-43; 44-45) are connected in parallel and sandwich the curved substructure beam. Thus a bimorph-style structure is formed. This modification can also be applied combined with other modifications, for example, coupling more half-tube elements in series.

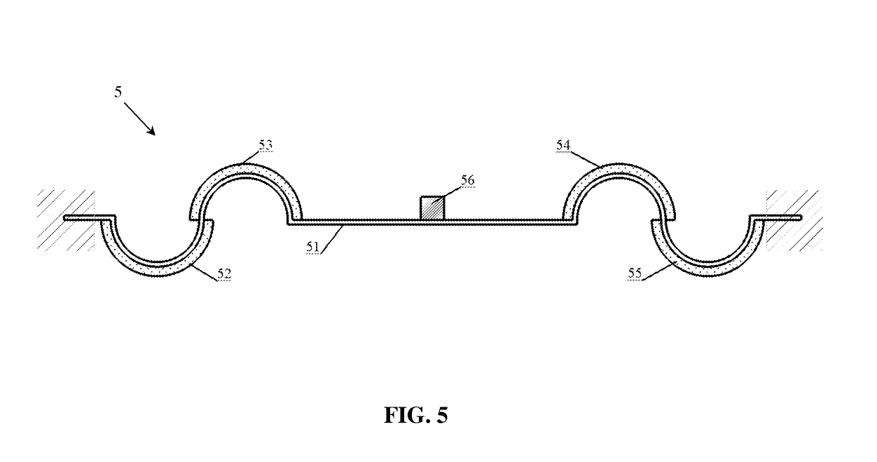

FIG. 5 shows a fifth embodiment 5 of the present invention with a fixed-fixed boundary condition. The substructure beam 51 is fixed at both ends with a vibration base. Half-tube piezoelectric elements 52, 53, 54 and 55 are mounted on the surface of a curved substructure beam 51. A mass block 56 is attached at the center of the embodiment. This nonlinearity is deliberately induced in this embodiment so that a broad frequency bandwidth is achieved. The half-tube piezoelectric elements on each side can be identical or different in terms of dimensions and directions. This configuration can be used in combination with piezoelectric configurations as stated in the prior embodiments.

The piezoelectric materials can be PZT, PVDF, Piezo fiber, ZnO, quartz, single crystal materials or other materials that show the piezoelectric effect.

In the aforementioned polarization process, piezo elements are poled in the radial direction, perpendicular to the outer & inner surfaces. However, the polarization can also be made in the circumferential direction, parallel to the outer & inner surfaces. In this polarization mode, shear stresses can be exploited.

For most energy harvesters where their core element is a 2-D piezoelectric plate, the stress is not evenly distributed. The nearer the piezoelectric element to the fixed end of the cantilever, the higher the electric potential it generates. The generated voltage deteriorates greatly as the piezoelectric element locates farther from the fixed end. However, in the present invention, the stress is much more evenly distributed. Even the parts of piezoelectric martials that are located far from the fixed end experience a high stress due to the 3-D curved topology of the combined system.

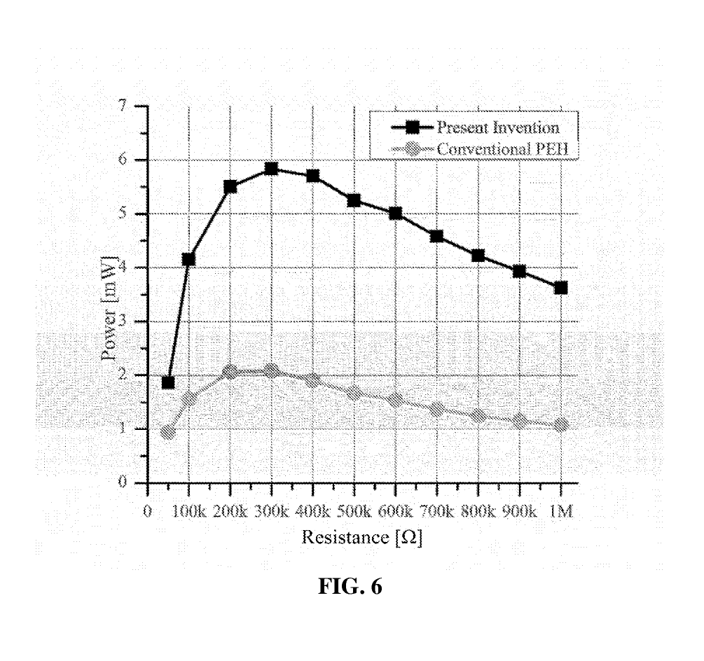

To validate this concept, the present device is compared with flat piezoelectric elements. A vibration harvester using a piezoelectric material of PZT-5H (d₃₁=−275×10⁻¹² C/N; g₃₁=−9.3×10⁻³ Vm/N) and having a half-tube shape with 20 mm in diameter, 0.5 mm in thickness and 15 mm in width is constructed. The half-tube piezoelectric element is made by grinding a piezo tube. The substructure beam is made of aluminum 3003 and molded by a designed molding die. A tip mass of 10 grams is added to the free end of the substructure beam. The overall length of the prototype is 100 mm. This device is compared with a cantilever energy harvester with a flat PZT-5H plate (0.5×15×40 mm³) and substructure beam (Aluminum 3003 0.5×15×100 mm³). The added tip mass is also 10 grams at the free end. All parameters and conditions are kept the same in the experiment. FIG. 6 shows the test results from both devices, showing that the present invention can generate about 300% more power than the flat type piezoelectric harvester under the same conditions.

The foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

What is claimed is:

1. A curved piezoelectric element based vibration energy harvester comprising:
a. a substructure beam having a first end, a second end and a longitudinal length, wherein said first end is fixed on a vibration base and said second end is free to vibrate;
b. said beam having at least one curved-section along its longitudinal length;
c. at least one curved-piezoelectric element shaped and sized to attach to said curved-section of said beam, thereby harvesting a mechanical energy from said vibration base; and
d. a mass block attached to said second end, said mass sized to control vibration of the beam,
whereby said harvester has a low resonance frequency and a high power output.

2. The vibration energy harvester of claim 1, wherein said curved-piezoelectric element is polarized radially, perpendicular to the inner and outer surfaces of the element.

3. The vibration energy harvester of claim 1, wherein said curved-piezoelectric element is polarized circumferentially, parallel to the inner and outer surfaces of the element, whereby shear mode harvesting is exploited.

4. The vibration energy harvester of claim 1, wherein said curved-piezoelectric element is a half-tube shaped piezoelectric element.

5. The vibration energy harvester of claim 1, wherein said curved-piezoelectric element is smaller or larger than a half-tube shaped.

6. The vibration energy harvester of claim 1, wherein said harvester has a plurality of curved-piezoelectric elements attached alternatively to opposite sides of said beam and electrically connected in series with each other.

7. The vibration energy harvester of claim 1, wherein said harvester has three curved-piezoelectric elements connected in series along the longitudinal length of the substructure beam.

8. The vibration energy harvester of claim 1, wherein said harvester has a bimorph-style composite structure, wherein two curved-piezoelectric elements are attached in parallel to both surfaces of each curved-section of the beam, sandwiching the curved-section, thereby a bimorph-style structure is formed.

9. The vibration energy harvester of claim 8, wherein each said curved-piezoelectric elements on each side of the beam are identical or different in terms of dimensions and polarization directions.

10. The vibration energy harvester of claim 1, wherein said curved-piezoelectric elements are made of any one of PZT, PVDF, Piezo fiber, ZnO, quartz, single crystal materials or other materials that show a piezoelectric effect.

11. A curved piezoelectric element based vibration energy harvester comprising:
a. a substructure beam having a first end, a second end, and a longitudinal length, wherein said first and second ends are fixed on a vibration base;
b. said beam having at least one curved-section along its longitudinal length;
c. at least one curved-piezoelectric element shaped and sized to attach to said curved-section of said beam, thereby harvesting a mechanical energy from said vibration base; and
d. a mass block attached to the center of the beam,
whereby a nonlinear vibration energy harvester is formed to harvest a broad frequency bandwidth.

12. The vibration energy harvester of claim 11, wherein said harvester has a plurality of curved-piezoelectric elements attached on each half of said beam and on each side of said mass block.

13. The vibration energy harvester of claim 11, wherein the number of curved-piezoelectric elements on each side of said mass block are the same or are different.

14. The vibration energy harvester of claim 11, wherein said curved-piezoelectric element is polarized radially, perpendicular to the inner and outer surfaces of the element.

15. The vibration energy harvester of claim 11, wherein said curved-piezoelectric element is polarized circumferentially, parallel to the inner and outer surfaces of the element, whereby shear mode harvesting is exploited.

16. The vibration energy harvester of claim 11, wherein said curved-piezoelectric element is a half-tube or smaller than a half-tube or larger than a half-tube shaped piezoelectric element.

17. The vibration energy harvester of claim 11, wherein said harvester has a bimorph-style composite structure, wherein two piezoelectric element are attached in parallel to both surfaces of each curved-section of the beam, sandwiching the curved section, thereby a bimorph-style structure is formed.

18. The vibration energy harvester of claim 17, wherein each said curved piezoelectric elements on each side are identical or different in terms of dimensions and directions.

19. The vibration energy harvester of claim 11, wherein said piezoelectric elements are made of any one of PZT, PVDF, Piezo fiber, ZnO, quartz, single crystal materials or other materials that show the piezoelectric effect.

20. The vibration energy harvester comprising:
a. a PZT-5H piezoelectric material forming a half-tube piezoelectric element with 20 mm diameter, 0.5 mm in thickness and 15 mm in width;
b. an aluminum beam having an overall length of 100 mm and having a curved section sized to receive and to attach to said piezoelectric element, said beam having a fixed end and a free end; and
c. a tip mass of 10 grams attached to the free end of the substructure beam, whereby said harvester can generate about 5.8 mW power.
